(19) United States
(12) Patent Application Publication
(10) Pub. No.: US 2026/0082692 A1
(43) Pub. Date: Mar. 19, 2026

(54) SEMICONDUCTOR DEVICE

(71) Applicant: INSTITUTE OF MICROELECTRONICS, CHINESE ACADEMY OF SCIENCES, Beijing (CN)

(72) Inventors: Yongliang LI, Beijing (CN); Longyu SUN, Beijing (CN); Huaizhi LUO, Beijing (CN); Jun LUO, Beijing (CN)

(73) Assignee: INSTITUTE OF MICROELECTRONICS, CHINESE ACADEMY OF SCIENCES, Beijing (CN)

(21) Appl. No.: 19/272,752

(22) Filed: Jul. 17, 2025

(30) Foreign Application Priority Data
Sep. 13, 2024 (CN) 202411288783.8

(51) Int. Cl. H10D 84/83; H01L 21/762

(52) U.S. Cl. CPC H10D 84/834; H10W 10/014; H10W 10/17

(57) ABSTRACT

Provided is a semiconductor device. The semiconductor device includes: a semiconductor substrate, a first gate-all-around transistor, a second gate-all-around transistor, an insulation layer, and first and second dielectric isolation layers. The insulation layer is arranged between a source/drain region of the first gate-all-around transistor and a source/drain region of the second gate-all-around transistor. The first dielectric isolation layers and the second dielectric isolation layers are alternately stacked between a channel region of the first gate-all-around transistor and a channel region of the second gate-all-around transistor. A gate stack structure of the first gate-all-around transistor and/or a gate stack structure of the second gate-all-around transistor is located at a periphery of alternately stacked first and second dielectric isolation layers. Film layers located at bottom and top layers in alternately stacked first and second dielectric isolation layers are both first dielectric isolation layer.

### CROSS REFERENCE TO RELATED APPLICATION(S)

This application claims benefit of the filing date to Chinese Patent Application No.202411288783.8 filed on Sep. 13, 2024, the disclosure of which is hereby incorporated in its entirety by reference.

### TECHNICAL FIELD

The present disclosure relates to the field of semiconductor technologies, and in particular to a semiconductor device.

### BACKGROUND

A three-dimensional stacked complementary transistor includes vertically stacked N-type transistors and P-type transistors, eliminating lateral spacing among the N-type transistors and the P-type transistors, which allows an effective channel width to be further increased, thereby contributing to improving a working performance and an integration of the semiconductor device.

However, in an existing three-dimensional stacked complementary transistor, a parasitic capacitance between a gate stack structure included in an upper-layer gate-all-around transistor and a gate stack structure included in a lower-layer gate-all-around transistor is large, leading to poor alternating current characteristics of the three-dimensional stacked complementary transistor.

### SUMMARY

The objective of the present disclosure is to provide a semiconductor device to reduce a parasitic capacitance between gate stack structures and improve alternating current characteristics of the semiconductor device, by providing a gate stack structure included in a first gate-all-around transistor and/or a gate stack structure included in a second gate-all-around transistor at a periphery of alternately stacked first dielectric isolation layers and second dielectric isolation layers.

In order to achieve the above purpose, a semiconductor device is provided, including: a semiconductor substrate; a first gate-all-around transistor arranged on the semiconductor substrate; a second gate-all-around transistor arranged above the first gate-all-around transistor, a conductivity type of the second gate-all-around transistor is opposite to a conductivity type of the first gate-all-around transistor; an insulation layer arranged between a source/drain region included in the first gate-all-around transistor and a source/drain region included in the second gate-all-around transistor; and first dielectric isolation layers and second dielectric isolation layers alternately stacked between a channel region included in the first gate-all-around transistor and a channel region included in the second gate-all-around transistor along a thickness direction of the semiconductor substrate, a gate stack structure included in the first gate-all-around transistor and/or a gate stack structure included in the second gate-all-around transistor is located at a periphery of the alternately stacked first dielectric isolation layers and second dielectric isolation layers, and film layers located at a bottom layer and a top layer in the alternately stacked first dielectric isolation layers and second dielectric isolation layers are both the first dielectric isolation layer.

In an example, the first dielectric isolation layer and the second dielectric isolation layer are not integrally formed.

In an example, a material of the second dielectric isolation layer and a material of the first dielectric isolation layer are the same.

In an example, a dielectric constant of a material of the second dielectric isolation layer is smaller than a dielectric constant of a material of the first dielectric isolation layer.

In an example, a material of the first dielectric isolation layer includes at least one of SiN, SiCO and SiCON.

In an example, a material of the second dielectric isolation layer includes at least one of SiO2, SiN, SiCO, SiCON and SiO2—SiF4.

In an example, a thickness of the first dielectric isolation layer and/or a thickness of the second dielectric isolation layer is greater than or equal to 10 nm and less than or equal to 30 nm.

In an example, the semiconductor device further includes a gate spacer at least arranged on two sides of the gate stack structure along a length direction of the gate stack structure, and the gate spacer and the first dielectric isolation layer are integrally formed; or the semiconductor device further includes a gate spacer at least arranged on two sides of the gate stack structure along a length direction of the gate stack structure, the gate spacer includes a first spacer and a second spacer stacked along the length direction of the gate stack structure, the second spacer is arranged on a side of the first spacer away from the gate stack structure, the first spacer and the first dielectric isolation layer are integrally formed, and the second spacer and the second dielectric isolation layer are integrally formed.

In an example, the first gate-all-around transistor and/or the second gate-all-around transistor further includes an inner spacer arranged between the gate stack structure and the source/drain region.

In an example, the inner spacers included in the first gate-all-around transistor and the second gate-all-around transistor are integrally formed.

In an example, a material of the gate stack structure included in the first gate-all-around transistor and a material of the gate stack structure included in the second gate-all-around transistor are different.

### BRIEF DESCRIPTION OF THE DRAWINGS

The accompanying drawings illustrated here are provided to provide a further understanding of the present disclosure and constitute a part of the present disclosure. The exemplary embodiments of the present disclosure and the descriptions thereof are used to explain the present disclosure and do not constitute an undue limitation of the present disclosure. In the accompanying drawings:

FIG. 1 is a longitudinal sectional view schematically showing a structure of a three-dimensional stacked complementary transistor in the related art;

FIG. 2 is a first longitudinal sectional view schematically showing a structure of a semiconductor device provided by the embodiments of the present disclosure;

FIG. 3 is a second longitudinal sectional view schematically showing a structure of a semiconductor device provided by the embodiments of the present disclosure;

FIG. 4 is a third longitudinal sectional view schematically showing a structure of a semiconductor device provided by the embodiments of the present disclosure; and

FIG. 5 is a fourth longitudinal sectional view schematically showing a structure of a semiconductor device provided by the embodiments of the present disclosure.

Reference signs: 11 Semiconductor substrate, 12 First gate-all-around transistor, 13 Second gate-all-around transistor, 14 Insulation layer, 15 First dielectric isolation layer, 16 Second dielectric isolation layer, 17 Source/drain region, 18 Channel region, 19 Gate stack structure, 20 Gate spacer, 21 First spacer, 22 Second spacer, 23 Inner spacer, 24 Shallow trench isolation structure, 25 Interlayer dielectric layer.

### DETAILED DESCRIPTION OF EMBODIMENTS

Hereinafter, the embodiments of the present disclosure will be described with reference to the accompanying drawings. It should be understood that these descriptions are only exemplary and are not intended to limit the scope of the present disclosure. In addition, in the following descriptions, descriptions of well-known structures and technologies are omitted to avoid unnecessarily confusing the concept of the present disclosure.

Various structural diagrams according to the embodiments of the present disclosure are shown in the drawings. These drawings are not drawn to scale, in which some details are exaggerated, while some details may be omitted for a clearer expression. Shapes of various regions, layers as well as the relative sizes and positional relationships thereof shown in the drawings are only exemplary, and may actually be deviated due to manufacturing tolerances or technical limitations. Moreover, those skilled in the art may additionally design regions/layers with different shapes, sizes and relative positions according to actual needs.

In the context of the present disclosure, when a layer/element is referred to as being “on” another layer/element, the layer/element may be directly on the another layer/element, or there may be an intervening layer/element therebetween. In addition, if a layer/element is “above” another layer/element in an orientation, the layer/element may be “below” the another layer/element when the orientation is reversed. In order to make the technical problems to be solved by the present disclosure, technical solutions and beneficial effects more clear, the present disclosure will be further explained in detail with the accompanying drawings and embodiments. It should be understood that the specific embodiments described here are only for explaining the present disclosure, and are not used to limit the present disclosure.

In addition, the terms “first” and “second” are only used for descriptive purposes, and may not be understood as indicating or implying relative importance or implicitly indicating the number of indicated technical features. Therefore, the features defined as “first” and “second” may explicitly or implicitly include one or more said features. In the descriptions of the present disclosure, the expression “plural” means two or more, unless otherwise specifically defined. The expression of “at least one” means one or more, unless otherwise specifically defined.

In the descriptions of the present disclosure, it should be noted that unless otherwise specified and limited, the terms “mounting”, “coupling” and “connection” should be understood in a broad sense. For example, it may be a fixed connection, a detachable connection or an integrated connection; it may be a mechanical connection or an electrical connection; it may be a direct connection or an indirect connection through an intermediate medium; or it may be an internal communication between two elements or an interaction between two elements. Those skilled in the art may understand the specific meanings of the above terms in the present disclosure according to specific situations.

A three-dimensional stacked complementary transistor includes vertically stacked N-type transistors and P-type transistors, eliminating lateral spacing among the N-type transistors and the P-type transistors, which allows an effective channel width to be further increased, thereby contributing to improving a working performance and an integration of the semiconductor device. However, in an existing three-dimensional stacked complementary transistor, a parasitic capacitance between a gate stack structure included in an upper-layer gate-all-around transistor and a gate stack structure included in a lower-layer gate-all-around transistor is large, leading to poor alternating current characteristics of the three-dimensional stacked complementary transistor.

Specifically, the existing three-dimensional stacked complementary transistor usually include a middle dielectric isolation layer arranged between a channel region included in the upper-layer gate-all-around transistor and a channel region included in the lower-layer gate-all-around transistor, so as to reduce a leakage or an interference between the upper-layer gate-all-around transistor and the lower-layer gate-all-around transistor. Moreover, different metal gate materials are used for the upper-layer gate-all-around transistor and the lower-layer gate-all-around transistor, it is necessary to fill a gate formation region with protective materials such as spin-coated carbon and etch back to expose only a nanostructure of the upper-layer gate-all-around transistor. At this time, if no middle dielectric isolation layer exists, during etching back of the above protective material, a portion of the protective material below the nanostructure of the upper-layer gate-all-around transistor is difficult to be cleaned, thereby affecting a subsequent formation of a first layer metal gate. In other words, the existence of the middle dielectric isolation layer is also beneficial to improving a yield of the semiconductor device.

In actual manufacturing processes, it is necessary to form a fin-like structure on a semiconductor substrate first. Along a thickness direction of the semiconductor substrate, the fin-like structure includes first sacrificial layers and channel layers that are alternately stacked, and second sacrificial layers and third sacrificial layers that are alternately stacked. The rest of the channel layer (used to form the channel region) will be released by selectively removing a part of the first sacrificial layer corresponding to the gate formation region, so as to form a gate stack structure surrounding a periphery of the rest of the channel layer. Subsequently, the middle dielectric isolation layer is formed by selectively etching the second sacrificial layer to isolate the gate stack structure of the upper-layer gate-all-around transistor from the gate stack structure of the lower-layer gate-all-around transistor included in the three-dimensional stacked complementary transistor. For the third sacrificial layer, in an existing manufacturing method, a material of the third sacrificial layer is the same as a material of the first sacrificial layer, so as to alleviate the problem of stress distribution and stress matching between films due to a significant difference in materials of the different sacrificial layers. At this time, when a corresponding operation is performed to the first sacrificial layer, the third sacrificial layer will also be affected correspondingly. In this case, as shown in FIG. 1, in the three-dimensional stacked complementary transistor formed by the existing manufacturing method, a gate stack structure will be subsequently formed at a position of a portion of the third sacrificial layer corresponding to the gate formation region, and the gate stack structure surrounds not only the periphery of the channel region, but also a periphery of the middle dielectric isolation layer. As a result, a parasitic capacitance between the gate stack structures included in the upper-layer gate-all-around transistor and the lower-layer gate-all-around transistor is large, leading to poor alternating current characteristics of the three-dimensional stacked complementary transistor.

In order to solve the above technical problems, the embodiments of the present disclosure provide a semiconductor device. In the semiconductor device provided by the embodiments of the present disclosure, in the alternately stacked first dielectric isolation layers and second dielectric isolation layers, the first dielectric isolation layer may reduce a leakage or an interference between the first gate-all-around transistor and the second gate-all-around transistor. The existence of the second dielectric isolation layer may prevent the gate stack structure from filling in a gap between the adjacent first dielectric isolation layers, so that the gate stack structure included in the first gate-all-around transistor and/or the gate stack structure included in the second gate-all-around transistor is only located at a periphery of the alternately stacked first dielectric isolation layers and second dielectric isolation layers, thereby reducing the parasitic capacitance between the gate stack structures and improving the alternating current characteristics of the semiconductor device.

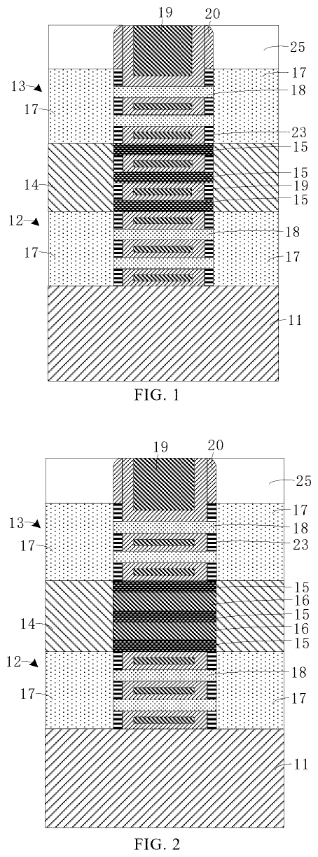

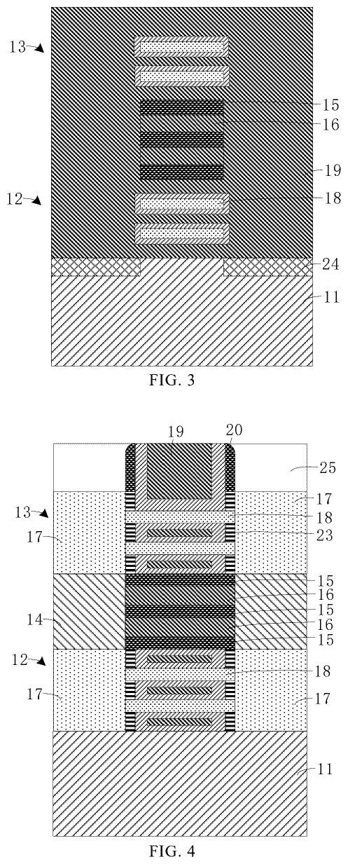

Specifically, as shown in FIG. 2, the semiconductor device provided by the embodiments of the present disclosure includes: a semiconductor substrate 11, a first gate-all-around transistor 12, a second gate-all-around transistor 13, an insulation layer 14, a first dielectric isolation layer 15 and a second dielectric isolation layer 16. The first gate-all-around transistor 12 is arranged on the semiconductor substrate 11. The second gate-all-around transistor 13 is arranged above the first gate-all-around transistor 13. A conductivity type of the second gate-all-around transistor 13 is opposite to a conductivity type of the first gate-all-around transistor 12. The insulation layer 14 is arranged between a source/drain region 17 included in the first gate-all-around transistor 12 and a source/drain region 17 included in the second gate-all-around transistor 13. Along a thickness direction of the semiconductor substrate 11, the first dielectric isolation layers 15 and the second dielectric isolation layers 16 are alternately stacked between a channel region 18 included in the first gate-all-around transistor 12 and a channel region 18 included in the second gate-all-around transistor 13. A gate stack structure 19 included in the first gate-all-around transistor 12 and/or a gate stack structure 19 included in the second gate-all-around transistor 13 is located at a periphery of the alternately stacked first dielectric isolation layers 15 and second dielectric isolation layers 16, and a top film layer and a bottom film layer in the alternately stacked first dielectric isolation layers 15 and second dielectric isolation layers 16 are both the first dielectric isolation layer 15.

In actual application processes, the embodiments of the present disclosure do not specifically limit the material and the structure of the semiconductor substrate, as long as it is applicable to the semiconductor device provided by the embodiments of the present disclosure.

Exemplarily, the semiconductor substrate may be a semiconductor substrate on which no structure is formed, such as a silicon substrate, a silicon-on-insulator substrate, a germanium silicon substrate or a germanium substrate.

Alternatively, the above-mentioned semiconductor substrate may be a semiconductor substrate on which some structures are formed. For example, when the semiconductor device in the embodiments of the present disclosure is a semiconductor device of a second or higher layer in an integrated circuit, the semiconductor substrate includes an interlayer dielectric layer and a semiconductor structure below the first gate-all-around transistor.

For the above first gate-all-around transistor and the second gate-all-around transistor, the embodiments of the present disclosure do not specifically limit the conductivity types of the first and second gate-all-around transistors, as long as the conductivity types of the second and first gate-all-around transistors are opposite. For example, the first gate-all-around transistor may be an N-type gate-all-around transistor, while the second gate-all-around transistor is a P-type gate-all-around transistor arranged above the N-type gate-all-around transistor. For another example, the first gate-all-around transistor may also be a P-type gate-all-around transistor, while the second gate-all-around transistor is an N-type gate-all-around transistor arranged above the P-type gate-all-around transistor.

In terms of structure, the first gate-all-around transistor and the second gate-all-around transistor may each include a channel region, a source/drain region and a gate stack structure. As shown in FIG. 2, in one and same first gate-all-around transistor 12 or same second gate-all-around transistor 13, the channel region 18 is located between source/drain regions 17, and two ends of the channel region 18 along a length direction are respectively in contact with the source/drain regions. The gate stack structure 19 surrounds the periphery of the channel region 18. The channel region 18 may include only one layer of nanostructures, or may also include a plurality of layers of nanostructures arranged at intervals along the thickness direction of the semiconductor substrate 11. In addition, the numbers of layers of nanostructures included in the first gate-all-around transistors 12 may be the same or different.

The materials of the source/drain region and the channel region above may include any semiconductor material selected from silicon, silicon germanium or germanium. The material of the source/drain region and/or the channel region included in the first gate-all-around transistor may be the same as or different from the material of the source/drain region and/or the channel region included in the second gate-all-around transistor. Secondly, the material of the channel region included in the first gate-all-around transistor may be the same as or different from the material of the source/drain region. The material of the channel region included in the second gate-all-around transistor may be the same as or different from the material of the source/drain region.

For the gate stack structure included in the first gate-all-around transistor and the gate stack structure included in the second gate-all-around transistor, a material of a gate dielectric layer included in the gate stack structure may include any insulating material selected from HfO₂, ZrO₂, TiO₂ or Al₂O₃. A material of a gate electrode may include any conductive material selected from TiN, TaN or TiSiN. The materials of the gate stack structure included in the first gate-all-around transistor and the gate stack structure included in the second gate-all-around transistor may be the same or different.

It should be noted that when the material of the gate stack structure included in the first gate-all-around transistor is different from the material of the gate stack structure included in the second gate-all-around transistor, the alternately stacked first dielectric isolation layers and second dielectric isolation layers may also provide a larger process window for manufacturing the gate stack structures of different materials, which is beneficial to improving the yield of the semiconductor device. The difference in material between the gate stack structure included in the first gate-all-around transistor and the gate stack structure included in the second gate-all-around transistor may refer to that: the materials of the gate dielectric layer included in the first gate-all-around transistor and the gate dielectric layer included in the second gate-all-around transistor are different (either partially or completely different), but the materials of the gate electrode included in the first gate-all-around transistor and the gate electrode included in the second gate-all-around transistor are the same. It may also refer to that: the materials of the gate dielectric layer included in the first gate-all-around transistor and the gate dielectric layer included in the second gate-all-around transistor are the same, but the materials of the gate electrode included in the first gate-all-around transistor and the gate electrode included in the second gate-all-around transistor are different (either partially or completely different). It may further refer to that: the materials of the gate dielectric layer included in the first gate-all-around transistor and the gate dielectric layer included in the second gate-all-around transistor are different (either partially or completely different), and the materials of the gate electrode included in the first gate-all-around transistor and the gate electrode included in the second gate-all-around transistor are also different (either partially or completely different).

In some cases, as shown in FIG. 3, the above semiconductor device may further include a shallow trench isolation structure 24. The shallow trench isolation structure 24 is arranged on the semiconductor substrate 11 for isolating different active regions on the semiconductor substrate 11, so as to prevent electric leakage.

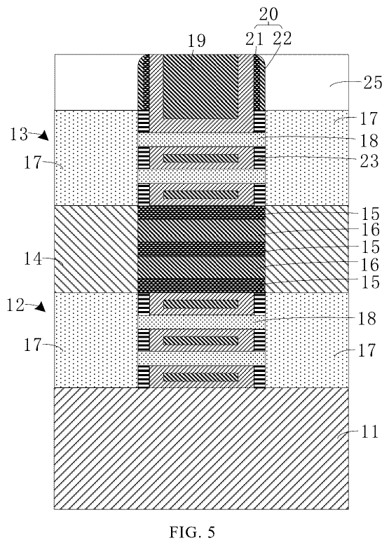

In some cases, as shown in FIG. 4, the above semiconductor device may further include a gate spacer 20 at least arranged on two sides of the gate stack structure 19 along a length direction of the gate stack structure, so as to isolate the gate stack structure 19 from other adjacent conductive structures and prevent leakage or interference. As shown in FIG. 4, the gate spacer 20 may be a single-layered structure. Alternatively, the gate spacer 20 may be a laminated structure. For example, as shown in FIG. 5, the gate spacer 20 includes a first spacer 21 and a second spacer 22 stacked along the length direction of the gate stack structure 19, and the second spacer 22 is arranged on a side of the first spacer 21 away from the gate stack structure 19. Specifically, the materials of the first spacer 21 and the second spacer 22 may be the same or different. The specific materials of the first spacer 21 and the second spacer 22 may be set according to actual manufacturing processes and actual demands, which will not be specifically limited here.

In some cases, as shown in FIG. 2, the first gate-all-around transistor 12 and/or the second gate-all-around transistor 13 described above may further include an inner spacer 23 arranged between the gate stack structure 19 and the source/drain region 17 to limit a length of the gate stack structure 19 and improve the yield of the semiconductor device. It is possible that only the first gate-all-around transistor includes the inner spacer, while the second gate-all-around transistor does not include the inner spacer. Alternatively, it is possible that the second gate-all-around transistor includes the inner spacer, while the first gate-all-around transistor does not include the inner spacer. Alternatively, as shown in FIG. 2, it is possible that both the first gate-all-around transistor 12 and the second gate-all-around transistor 13 include the above inner spacer 23. In this case, in actual manufacturing processes, the inner spacers 23 included in the first gate-all-around transistor 12 and the second gate-all-around transistor 13 may be integrally formed, so as to improve a manufacturing efficiency of the semiconductor device and is conducive to reducing manufacturing costs of the semiconductor device. Alternatively, the inner spacers 23 included in the first gate-all-around transistor 12 and the second gate-all-around transistor 13 may be respectively formed in different operation steps.

In some cases, as shown in FIG. 2, the above semiconductor device may further include an interlayer dielectric layer 25 arranged on the semiconductor substrate 11. A top portion of the interlayer dielectric layer 25 is flush with a top portion of the gate stack structure 19 included in the second gate-all-around transistor 13, so as to protect the source/drain region 17 from being affected by operations such as etching or cleaning, thereby improving the yield of the semiconductor device.

In terms of material, the materials of the shallow trench isolation structure, the gate spacer and the inner spacer may be set according to actual manufacturing processes and actual demands, which will not be specifically limited here. Exemplarily, the materials of the shallow trench isolation structure, the gate spacer or the inner spacer may include any insulating material selected from silicon oxide or silicon nitride.

For the above insulation layer, the insulation layer is arranged between the source/drain region included in the first gate-all-around transistor and the source/drain region included in the second gate-all-around transistor, and is used for electrically isolating the two source/drain regions with opposite conductivity types. On this basis, a thickness of the above insulation layer may be determined according to leakage prevention requirements for the two source/drain regions with opposite conductivity types in practical application scenarios, which will not be specifically limited here. The material of the insulation layer may include any insulating material selected from silicon oxide, silicon nitride, silicon oxynitride or silicon oxycarbide.

For the first dielectric isolation layer and the second dielectric isolation layer, the numbers of layers of the first dielectric isolation layer and the second dielectric isolation layer may be determined according to the thicknesses of the single-layered first dielectric isolation layer and the single-layered second dielectric isolation layer and the thickness of the insulation layer, as long as a total thickness of the alternately stacked first dielectric isolation layers and second dielectric isolation layers is approximately the same as a total thickness of the insulation layer.

The thicknesses of the single-layered first dielectric isolation layer and the single-layered second dielectric isolation layer may be set according to actual manufacturing processes and actual requirements, which will not be specifically limited here.

Exemplarily, as shown in FIG. 4, in the case that the semiconductor device further includes the gate spacer 20, and the gate spacer 20 and the first dielectric isolation layer 15 are integrally formed, the material of the first dielectric isolation layer 15 is the same as the material of the gate spacer 20, and the thickness of the single-layered first dielectric isolation layer 15 is less than or equal to the thickness of the gate spacer 20.

It should be noted that in the case that the semiconductor device further includes the gate spacer, the gate spacer may also be manufactured and formed separately from the first dielectric isolation layer in different operation steps. At this time, the material of the first dielectric isolation layer may be the same as or different from the material of the gate spacer. The thickness of the first dielectric isolation layer may be greater than, equal to or less than the thickness of the gate spacer.

For example, as shown in FIG. 5, in the case that the semiconductor device further includes the gate spacer 20, the first spacer 21 included in the gate spacer 20 and the first dielectric isolation layer 15 are integrally formed, and the second spacer 22 and the second dielectric isolation layer 16 are integrally formed, the material of the first dielectric isolation layer 15 is the same as the material of the first spacer 21, and the thickness of the single-layered first dielectric isolation layer 15 may be less than or equal to the thickness of the first spacer 21; the material of the second dielectric isolation layer 16 is the same as the material of the second spacer 22, and the thickness of the single-layered second dielectric isolation layer 16 may be less than or equal to the thickness of the second spacer 22.

It should be noted that, in the case that the semiconductor device further includes the first spacer and the second spacer, the first spacer and the first dielectric isolation layer may also be manufactured and formed separately in different operation steps, while the second spacer and the second dielectric isolation layer may also be manufactured and formed separately in different operation steps. On this basis, the material of the first dielectric isolation layer may be the same as or different from the material of the first spacer. The thickness of the first dielectric isolation layer may be greater than, equal to or less than the thickness of the first spacer. The material of the second dielectric isolation layer may be the same as or different from the material of the second spacer. The thickness of the second dielectric isolation layer may be greater than, equal to or less than the thickness of the second spacer.

For a specific thickness of the first dielectric isolation layer, exemplarily, the thickness of the first dielectric isolation layer and/or the second dielectric isolation layer may be greater than or equal to 10 nm and less than or equal to 30 nm. For example, the thickness of the first dielectric isolation layer and/or the second dielectric isolation layer may be 10 nm, 12 nm, 15 nm, 18 nm, 20 nm, 22 nm, 25 nm, 28 nm or 30 nm, etc. In this case, it may be understood that during manufacture of the first gate-all-around transistor, the second gate-all-around transistor, the insulation layer, and the alternately stacked first dielectric isolation layers and second dielectric isolation layers on the semiconductor substrate, firstly, a fin-like structure is formed on the semiconductor substrate, portions of the fin-like structure corresponding to the alternately stacked first dielectric isolation layers and second dielectric isolation layers are formed with corresponding sacrificial layers. The materials of two sacrificial layers respectively corresponding to the first dielectric isolation layer and the second dielectric isolation layer may be different, so as to respectively manufacture the first dielectric isolation layer and the second dielectric isolation layer (i.e., the first dielectric isolation layer and the second dielectric isolation layer are not integrally formed), and prevent high difficulty of simultaneously filling and forming the first dielectric isolation layer and the second dielectric isolation layer in a larger space. On this basis, when the thickness of the first dielectric isolation layer and/or the second dielectric isolation layer is within the above range, it is indicated that the thickness of the corresponding sacrificial layer is also within the above range. At this time, the thickness of the sacrificial layer is relatively large and the materials of different sacrificial layers are similar. Therefore, a limit of epitaxial critical thickness may be reduced, and there is no need to form more different sacrificial layers with smaller layer thickness as in the existing manufacturing methods, or there is no need to form different sacrificial layers with fixed number of layers due to the limit of the critical thickness, resulting in a small thickness of the insulation layer for isolating the source/drain regions with opposite conductivity types, so as to prevent leakage.

For the materials of the second dielectric isolation layer and the first dielectric isolation layer, the materials of the second dielectric isolation layer and the first dielectric isolation layer may be the same. At this time, after the second dielectric isolation layer and the first dielectric isolation layer are formed, during source-drain etching of the fin-like structure, after the sacrificial layer and the channel layer which are made of semiconductor materials and located above the second dielectric isolation layer and the first dielectric isolation layer are removed by an etchant, the second dielectric isolation layer and the first dielectric isolation layer may be etched using one and same etchant without changing the etchant, which improves an etching efficiency and reduces a manufacturing difficulty of the semiconductor devices.

Alternatively, the materials of the second dielectric isolation layer and the first dielectric isolation layer may be different. At this time, the material of the second dielectric isolation layer and the material of the first dielectric isolation layer may be respectively set according to different actual needs.

For example, a dielectric constant of the material of the second dielectric isolation layer may be smaller than a dielectric constant of the material of the first dielectric isolation layer. In this case, since the dielectric constant of the material of the second dielectric isolation layer is directly proportional to a size of the parasitic capacitance between the gate stack structures included in the first gate-all-around transistor and the second gate-all-around transistor, when the dielectric constant of the material of the second dielectric isolation layer is smaller than the dielectric constant of the material of the first dielectric isolation layer, it is beneficial to further reducing the parasitic capacitance between the above two gate stack structures and further improving the alternating current characteristics of the semiconductor device.

For the specific materials of the first dielectric isolation layer and the second dielectric isolation layer, exemplarily, the material of the first dielectric isolation layer may include at least one of SiN, SiCO and SiCON.

Exemplarily, the material of the second dielectric isolation layer may include at least one of SiO₂, SiN, SiCO, SiCON and SiO₂—SiF₄.

In the case of adopting the above technical solution, as shown in FIG. 2, in the semiconductor device provided by the embodiments of the present disclosure, the insulation layer 14 may electrically isolate the two source/drain regions 17 with opposite conductivity types which are arranged at intervals along the thickness direction of the semiconductor substrate 11, thereby improving an electrical reliability of the semiconductor device. In addition, not only the first dielectric isolation layers 15 for reducing leakage and interference is provided between the channel region 18 included in the first gate-all-around transistor 12 and the channel region 18 included in the second gate-all-around transistor 13, but also the second dielectric isolation layers 16 alternately stacking the first dielectric isolation layers 15 are provided. At this time, the spacing between the first gate-all-around transistor 12 and the second gate-all-around transistor 13 is relatively large in order to ensure sufficient insulating characteristics of the insulation layer 14, and a plurality layers of first dielectric isolation layers 15 distributed at intervals along the thickness direction of the semiconductor substrate 11 are provided between the channel regions 18, the existence of the second dielectric isolation layer 16 may fill the gap between adjacent first dielectric isolation layers 15. At this time, during formation of the gate stack structure 19, the existence of the second dielectric isolation layer 16 may prevent the gate stack structure 19 from filling in the gap between adjacent first dielectric isolation layers 15, so that the gate stack structure 19 included in the first gate-all-around transistor 12 and/or the gate stack structure 19 included in the second gate-all-around transistor 13 is only located at the periphery of the alternately stacked first dielectric isolation layers 15 and the second dielectric isolation layers 16, thereby increasing the thickness of the middle dielectric, reducing the parasitic capacitance between the gate stacked structures 19, and improving the alternating current characteristics of the semiconductor device.

The embodiments of the present disclosure provide a method for manufacturing the semiconductor device described above. The method for manufacturing the semiconductor device includes the steps as follows.

First, a fin-like structure may be formed on a semiconductor substrate by epitaxy and selective etching processes. Along a thickness direction of the semiconductor substrate, the fin-like structure includes first sacrificial layers and channel layers that are alternately stacked, as well second sacrificial layers and third sacrificial layers that are alternately stacked. In the thickness direction, the alternately stacked first sacrificial layers and channel layers are located on two sides of the alternately stacked second sacrificial layers and third sacrificial layers. The film layers located at a bottom layer and a top layer in the alternately stacked first sacrificial layers and channel layers are both the first sacrificial layer. The film layers located at a bottom layer and a top layer in the alternately stacked second sacrificial layers and third sacrificial layers are both the second sacrificial layer.

Specifically, the first sacrificial layer, the second sacrificial layer and the third sacrificial layer respectively have different functions. Specifically, the rest of the channel layer (used to form a channel region) will be later released by selectively removing a part of the first sacrificial layer corresponding to a gate formation region, so as to form a gate stack structure surrounding a periphery of the rest of the channel layer. Subsequently, a first dielectric isolation layer for isolating the gate stack structure of an upper-layer gate-all-around transistor from the gate stack structure of a lower-layer gate-all-around transistor included in a three-dimensional stacked complementary transistor is formed by selectively etching the second sacrificial layer. For the third sacrificial layer, a second dielectric isolation layer for isolation and blocking is formed at a position of a portion of the third sacrificial layer corresponding to the gate formation region. On this basis, it is necessary to have a certain etching selectivity ratio among the first sacrificial layer, the second sacrificial layer and the third sacrificial layer to achieve separate release.

Specifically, the materials of the second sacrificial layer and the third sacrificial layer may both be different from the material of the first sacrificial layer, and the materials of the second sacrificial layer and the third sacrificial layer may be different. Alternatively, the materials of the second sacrificial layer and the third sacrificial layer may be the same, and the second sacrificial layer is doped with an etching assistant to accelerate etching.

Exemplarily, the material of one of the second sacrificial layer and the third sacrificial layer may include silicon or silicon germanium, and the material of the other may include silicon germanium or germanium. A difference of germanium content between the second sacrificial layer and the third sacrificial layer is less than 15%, and the second sacrificial layer is doped with an etching assistant. The etching assistant may be an N-type dopant (such as phosphorus or arsenic). A doping concentration of the etching assistant in the second sacrificial layer may be determined according to the etching requirements for the second sacrificial layer in actual application scenarios, which will not be specifically limited here. Exemplarily, the doping concentration of the etching assistant in the above second sacrificial layer may be greater than or equal to 1E18cm⁻³ and less than or equal to 1E19cm⁻³.

Next, a mask structure spanning across the fin-like structure may be formed by processes such as deposition and etching. The mask structure may include a sacrificial gate (or a sacrificial gate and a gate oxide layer).

Then, the second sacrificial layer is selectively removed to form a first dielectric filling region, while the first sacrificial layer and the third sacrificial layer are remained. At this time, the second sacrificial layer may be selectively etched only based on the difference between the material of the second sacrificial layer and the material of each of the first sacrificial layer and the third sacrificial layer, and/or the second sacrificial layer may be selectively etched at least under an accelerated etching effect of the etching assistant.

The process of selective etching and the type of the etchant may be determined according to the material of the second sacrificial layer and the type of the etching assistant, which will not be specifically limited here.

Exemplarily, in the case that the second sacrificial layer is selectively removed by a wet etching process, a wet etching solution may include a mixed solution of hydrofluoric acid and hydrogen peroxide.

Exemplarily, in the case that the second sacrificial layer is selectively removed by a dry etching process, the etching gas includes a mixed gas of CF₄, O₂ and He.

Subsequently, the first dielectric isolation layer may be formed in the first dielectric filling region by processes such as deposition and etching.

Afterwards, the first sacrificial layer, the channel layer, the first dielectric isolation layer and the third sacrificial layer not covered by the mask structure are removed.

In actual manufacturing processes, after the first dielectric isolation layer is formed, the first sacrificial layer, the channel layer, the first dielectric isolation layer and the third sacrificial layer not covered by the mask structure may be removed together, so as to facilitate a subsequent formation of the source/drain region.

Alternatively, when the material of the first sacrificial layer is different from the material of the third sacrificial layer, the third sacrificial layer may also be selectively removed by wet etching or dry etching to form a third dielectric filling region. Next, a second dielectric isolation layer is formed in the third dielectric filling region by processes such as deposition and etching. Then, the first sacrificial layer, the channel layer, the first dielectric isolation layer and the second dielectric isolation layer not covered by the mask structure are removed by processes such as wet etching or dry etching. In this case, when the gate stack structure is formed subsequently, the gate stack structure will not be filled in the gap between two adjacent first dielectric isolation layers, thereby reducing the parasitic capacitance and further improving the working performance of the manufactured semiconductor device.

Next, the source/drain region included in the first gate-all-around transistor may be respectively formed on two sides of the rest of the first sacrificial layer and the channel layer located below the rest of the first dielectric isolation layer by processes such as epitaxy.

Subsequently, an insulation layer may be formed on the source/drain region included in the first gate-all-around transistor by processes such as deposition and etching.

Afterwards, the source/drain region included in the second gate-all-around transistor may be respectively formed on the insulation layer and on two sides of the rest of the first sacrificial layer and the channel layer above the rest of the first dielectric isolation layer. The conductivity type of the source/drain region included in the second gate-all-around transistor is opposite to the conductivity type of the source/drain region included in the first gate-all-around transistor.

Then, an interlayer dielectric layer covering the semiconductor substrate may be formed by processes such as deposition and planarization. A top portion of the interlayer dielectric layer is flush with a top portion of the mask structure.

Next, the mask structure is removed by processes such as wet etching or dry etching.

It should be noted that if the second dielectric isolation layer is not formed in the above text, after the interlayer dielectric layer is formed and the mask structure is removed, the rest of the third sacrificial layer may be removed by processes such as wet etching or dry etching to obtain a second dielectric filling region. Then, a second dielectric isolation layer is formed in the second dielectric filling region by processes such as deposition and etching.

If the second dielectric isolation layer has been formed before the source/drain region included in the first gate-all-around transistor is formed, the subsequent operations may be directly performed.

Then, the rest of the first sacrificial layer is removed by processes such as wet etching or dry etching.

Afterwards, a gate stack structure surrounding the periphery of the rest of the channel layer is formed by processes such as atomic layer deposition.

In the above descriptions, the technical details such as patterning and etching of each layer are not explained in detail. However, those skilled in the art should understand that layers, regions etc., with a desired shape may be formed by various technical means. In addition, in order to form one and same structure, those skilled in the art may also design methods that are not exactly the same as those described above. In addition, although various embodiments have been described separately above, this does not mean that the measures in the various embodiments may not be advantageously used in combination.

The embodiments of the present disclosure have been described above. However, these embodiments are only for a clearer explanation, and are not intended to limit the scope of the present disclosure. The scope of the present disclosure is defined by the appended claims and the equivalents thereof. Without departing from the scope of the present disclosure, those skilled in the art may make various substitutions and modifications, and these substitutions and modifications should all fall within the scope of the present disclosure.

What is claimed is:

1. A semiconductor device, comprising:
a semiconductor substrate;
a first gate-all-around transistor arranged on the semiconductor substrate;
a second gate-all-around transistor arranged above the first gate-all-around transistor, wherein a conductivity type of the second gate-all-around transistor is opposite to a conductivity type of the first gate-all-around transistor;
an insulation layer arranged between a source/drain region comprised in the first gate-all-around transistor and a source/drain region comprised in the second gate-all-around transistor; and
first dielectric isolation layers and second dielectric isolation layers alternately stacked between a channel region comprised in the first gate-all-around transistor and a channel region comprised in the second gate-all-around transistor along a thickness direction of the semiconductor substrate, a gate stack structure comprised in the first gate-all-around transistor and/or a gate stack structure comprised in the second gate-all-around transistor is located at a periphery of the alternately stacked first dielectric isolation layers and second dielectric isolation layers, and film layers located at a bottom layer and a top layer in the alternately stacked first dielectric isolation layers and second dielectric isolation layers are both the first dielectric isolation layer.

2. The semiconductor device according to claim 1, wherein the first dielectric isolation layer and the second dielectric isolation layer are not integrally formed.

3. The semiconductor device according to claim 1, wherein a material of the second dielectric isolation layer and a material of the first dielectric isolation layer are the same.

4. The semiconductor device according to claim 1, wherein a dielectric constant of a material of the second dielectric isolation layer is smaller than a dielectric constant of a material of the first dielectric isolation layer.

5. The semiconductor device according to claim 1, wherein a material of the first dielectric isolation layer comprises at least one of SiN, SiCO and SiCON; and/or
a material of the second dielectric isolation layer comprises at least one of SiO₂, SiN, SiCO, SiCON and SiO₂—SiF₄.

6. The semiconductor device according to claim 1, wherein a thickness of the first dielectric isolation layer and/or a thickness of the second dielectric isolation layer is greater than or equal to 10 nm and less than or equal to 30 nm.

7. The semiconductor device according to claim 1, wherein the semiconductor device further comprises a gate spacer at least arranged on two sides of the gate stack structure along a length direction of the gate stack structure, and the gate spacer and the first dielectric isolation layer are integrally formed; or
the semiconductor device further comprises a gate spacer at least arranged on two sides of the gate stack structure along a length direction of the gate stack structure, the gate spacer comprises a first spacer and a second spacer stacked along the length direction of the gate stack structure, the second spacer is arranged on a side of the first spacer away from the gate stack structure, the first spacer and the first dielectric isolation layer are integrally formed, and the second spacer and the second dielectric isolation layer are integrally formed.

8. The semiconductor device according to claim 1, wherein the first gate-all-around transistor and/or the second gate-all-around transistor further comprises an inner spacer arranged between the gate stack structure and the source/drain region.

9. The semiconductor device according to claim 8, wherein the inner spacers comprised in the first gate-all-around transistor and the second gate-all-around transistor are integrally formed.

10. The semiconductor device according to claim 1, wherein a material of the gate stack structure comprised in the first gate-all-around transistor and a material of the gate stack structure comprised in the second gate-all-around transistor are different.
